(19) United States
(12) Patent Application Publication
(10) Pub. No.: US 2017/0257981 A1
(43) Pub. Date: Sep. 7, 2017

(54) Thermal Regulation System for Electronic Components

(71) Applicant: L-3 Communications Corporation, New York, NY (US)

(72) Inventor: Richard M. WEBER, Prosper, TX (US)

(73) Assignee: L-3 Communications Corporation, New York, NY (US)

(21) Appl. No.: 15/060,366

(22) Filed: Mar. 3, 2016

(51) Int. Cl. H05K 7/20; F25B 1/00; F28F 23/00; F28D 15/00; F28F 13/08

(52) U.S. Cl. CPC H05K 7/20281; F28D 15/00; F28F 13/08; F28F 23/00; F25B 1/00; H05K 7/20272; H05K 7/20236; F28D 2021/0028

(57) ABSTRACT

A system and method are provided for temperature regulation of an electronic component. A nozzle produces a jet of coolant that impinges on the electronic component. The jet and the electronic component are submerged in a volume of the coolant. The system further includes a heat exchanger and a pump. The pump moves a flow of coolant from the volume of coolant, through the heat exchanger, and into the nozzle, thereby forming the jet of coolant. The system may also include a heater that heats the coolant as it passes from the pump to the nozzle. The system may include a plurality of jets and a corresponding plurality of electronic components submerged in the volume of coolant.

### TECHNICAL FIELD

The present application relates generally to cooling systems for electronic components and, more specifically, to a thermal regulation system for electronic components.

### BACKGROUND

High power phased array systems produce high heat loads using components that run with high heat fluxes. At start up, the temperature of all elements of a phased array may have equalized to the system's current ambient temperature. When the current ambient temperature is low (e.g., below 0° C.), this condition is often referred to as being “cold soaked” or “soaked.”

System requirements may state that a system must be able to start up when soaked to −20° C., −50° C., or colder. Such systems are typically required to be able to begin operation at such soak temperatures and, after a specified length of time, be able to operate with full performance. Some system components are not able to operate reliably, or without being damaged, below −20° C.

There are electronic systems that have to use liquid cooling due to the high heat loads and fluxes, but are not able to “start” when soaked at temperatures as low as −50° C., or lower. This may be because the traditionally used coolants either freeze or are so viscous they will not flow. This is an issue as heat that may be generated in an assembly may not be able to be transported as the unheated lines, loop filter, and pump are essentially plugged with frozen or sludge-like coolant.

Some phased array systems use heat generated by its electronic components to “warm-up” the system until an acceptable operating temperature is reached. But this is of limited utility because the electronics have to be run in ways to not produce their full heat load, to prevent potentially unstable operation of active devices and to not exceed the heat transport capability of a highly viscous or frozen coolant in the coolant lines.

A typical requirement is for military phase arrays is to be able to start at −54° C. Newer applications have the goal to be able to start at lower temperatures such as −80° C.

A cooling system architecture is needed that can remove high heat loads from an electronics system, such as a phased array, that uses devices that produce high heat fluxes. In addition, it must be able to “start” at temperatures near −80° C.

High heat load electronic systems, such as phased arrays with high heat flux components, require some form of liquid cooling to absorb and transport the waste heat. Typically the coolants used are:
Polyalphaolefin (PAO): At −40° C. or lower PAO will essentially not flow due to its viscosity.
A mixture of propylene glycol and water (PGW): Lowest freezing point mixture (60/40) freezes at −48° C. Does not support −54° C. or a lower soak temperature.
A mixture of ethylene glycol and water (EGW): Lowest freezing point mixture (60/40) freezes at −53° C. Essentially supports −54° C., but not a lower soak temperature of −80° C.

PAO, PGW, and EGW are typically used with coldplates or coldwalls to which the heat producing devices are mounted so the heat can be absorbed by a flowing coolant stream that transports the heat out of the electronics system. Even though waste heat may be produced to warm the coolant in the coldwalls, when cold soaked below 50° C., the coolant in the lines, in an in-line filter, and in the pump will be essentially be plugged up with frozen or highly viscous coolant. As a result, the warming waste heat cannot be transported to effect warming of the entire loop. With such a system, warm-up at −80° C. would require heated coolant lines, a heated filter assembly and a heated pump. In addition, there may be potential burst problems with EGW and PGW as it freezes inside coldwalls and metal coolant lines.

For systems that are cold soaked, but the coolant is not frozen (e.g. soak temperatures above −30° C.), heat generated by its electronics could be used to “warm-up” the system until an acceptable temperature is reached. This approach is of limited utility because the electronics have to be sequenced or operated in ways to not produce a full heat load, in order to prevent potentially unstable operation of the active electronic devices and to prevent damage to them. In addition, the electronics should not be operated in such a way that the system exceeds the heat transport capability of a viscous or near frozen coolant in the coolant lines. Still further, there may be transient temperature gradients that can cause mechanical or structural failures induced by differential expansion rates within and among system components.

### SUMMARY

In a first embodiment, a temperature regulation system for an electronic component includes a nozzle that is configured to produce a jet of coolant that impinges on the electronic component. The jet and the electronic component are submerged in a volume of the coolant. The system further includes a heat exchanger and a pump. The pump is configured to move a flow of coolant from the volume of coolant, through the heat exchanger, and into the nozzle, thereby forming the jet of coolant. The embodiment may include a heater configured to heat the coolant as it passes from the pump to the nozzle. The embodiment may include a plurality of jets producing a corresponding plurality of jets of coolant that impinge on a corresponding plurality of electronic components, where each jet and each electronic component is submerged in the volume of coolant.

In a second embodiment, a method of regulating the temperature of an electronic component includes producing a jet of coolant that impinges on the electronic component. The jet and the electronic component are submerged in a volume of the coolant. The method further includes pumping a first flow of coolant from the volume of coolant, through a heat exchanger, and into the nozzle.

Before undertaking the DETAILED DESCRIPTION below, it may be advantageous to set forth definitions of certain words and phrases used throughout this patent document: the terms “include” and “comprise,” as well as derivatives thereof, mean inclusion without limitation; the term “or,” is inclusive, meaning and/or; the phrases “associated with” and “associated therewith,” as well as derivatives thereof, may mean to include, be included within, interconnect with, contain, be contained within, connect to or with, couple to or with, be communicable with, cooperate with, interleave, juxtapose, be proximate to, be bound to or with, have, have a property of, or the like; and the term “controller” means any device, system or part thereof that controls at least one operation, such a device may be implemented in hardware, firmware or software, or some combination of at least two of the same. It should be noted that the functionality associated with any particular controller may be centralized or distributed, whether locally or remotely. Definitions for certain words and phrases are provided throughout this patent document, those of ordinary skill in the art should understand that in many, if not most instances, such definitions apply to prior, as well as future uses of such defined words and phrases.

### BRIEF DESCRIPTION OF THE DRAWINGS

For a more complete understanding of the present disclosure and its advantages, reference is now made to the following description taken in conjunction with the accompanying drawings, in which like reference numerals represent like parts:

FIG. 1 illustrates a schematic diagram of a thermal regulation system for electronic components according to an embodiment of the disclosure.

FIG. 2 illustrates an electronics enclosure according to an embodiment of the disclosure.

### DETAILED DESCRIPTION

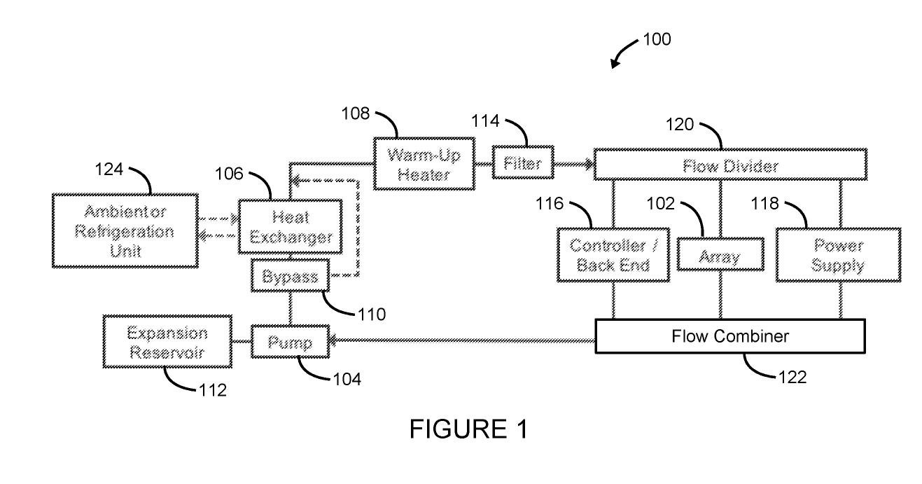

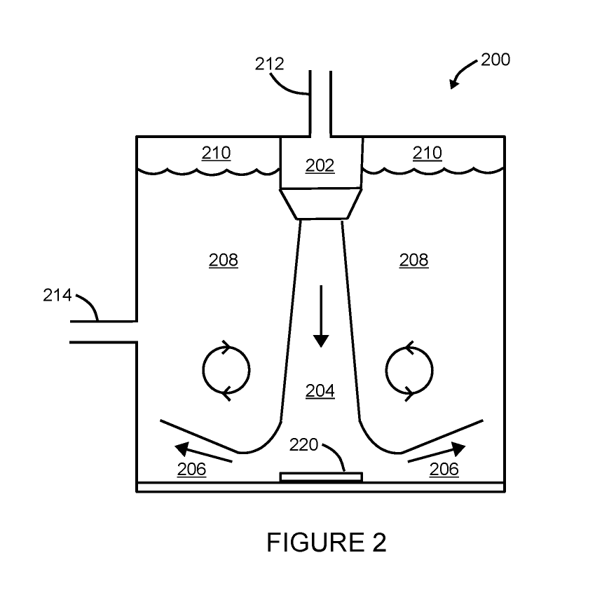

FIGS. 1 and 2, discussed below, and the various embodiments used to describe the principles of the present disclosure in this patent document are by way of illustration only and should not be construed in any way to limit the scope of the disclosure. Those skilled in the art will understand that the principles of the present disclosure may be implemented in any suitably arranged thermal regulation system for electronic components.

FIG. 1 illustrates a schematic diagram of a thermal regulation system for electronic components 100 according to one embodiment of the disclosure. An enclosure 102 includes at least one electronic component, and may include an array of electronic components. A more detailed discussion of the enclosure 102 is provided below, with reference to FIG. 2.

A flow of coolant or other thermal working fluid is pumped from the enclosure 102 by a pump 104, through a heat exchanger 106, and back through the enclosure 102. Physical characteristics of the coolant are discussed in greater detail below. Embodiments of the system 100 intended for cold soaked start up further include a heater 108 to heat the coolant and raise the temperature of the electronic components in the enclosure 102 to a safe operating temperature. Such embodiments may also include a bypass valve 110, to route the coolant around the heat exchanger 106 in order to speed warm up of the electronic components. In other such embodiments, the heater 108 may be located between the pump and the bypass valve 110.

Embodiments of the system 100 may further include an expansion reservoir 112 coupled to the pump to respond to changes in the volume of coolant in the system 100 caused by changes in the temperature of the coolant. The system 100 may also include a filter 114 to trap particulate matter in the coolant.

In some embodiments, the heat exchanger 106 is exposed to ambient air or water to carry away heat. Such air or water may pass over the heat exchanger 106 through motion of the system 100 through the air or water, or as a result of the action of a fan or other impeller. In other embodiments, the heat exchanger 106 is thermally coupled to a refrigeration system 124 that is configured to remove heat from the heat exchanger 106 using a second working fluid.

In still other embodiments, the system 100 may include additional electronic enclosures or subsystems, such as a controller/back end system 116 and/or a power supply 118. In FIG. 1, the flow of coolant from the heat exchanger 106 is split into separate flows by a flow divider 120, the separate flows pass in parallel through the enclosures 102, 116, and 118, and then are recombined in a flow combiner 122 into a single coolant flow for passage through the pump 104 and the heat exchanger 106. It will be understood that in other embodiments, the enclosures 102, 116, and 118 may be arranged in series, such that a single flow of coolant is configured to heat or cool all the enclosures. In still other embodiments the enclosures 102, 116, and 118 may be arranged in a series/parallel combination. In any embodiment having additional enclosures, the electronic components of one or more of those enclosures may be cooled using a conventional heat transfer mounting component such as a cold plate or cold wall, rather than the submerged jet impingement enclosure described below with reference to FIG. 2.

FIG. 2 illustrates an electronics enclosure 200 according to an embodiment of the disclosure. In some embodiments, the enclosure 200 may be used as the enclosure 102 in the system 100 described with reference to FIG. 1. The enclosure 200 contains a volume of coolant 208. While the enclosure 200 is shown in FIG. 2 as including air 210 above the volume of coolant 208, it will be understood that in other embodiments the enclosure 200 is filled with coolant and has substantially no air 210 in the enclosure.

A flow of coolant enters the enclosure 200 via an inlet 212 into a nozzle 202 that forms a jet of coolant 204 that impinges on at least one external surface of an electronic device 220. At least the outlet of the nozzle 202 is submerged in the volume of coolant 208. The jet 204 is fully submerged within the volume of coolant 208. Once the jet 204 impinges on the electronic device 220, it is diverted away and forms a so-called wall jet 206. The velocity of the wall jet 206 diminishes with distance from the electronic device 220 until the wall jet 206 intermingles with the volume of coolant 208, causing turbulance.

The wall jet 206 is heated by the electronic device 220 and its movement carries the heat into the volume of coolant 208. As described with reference to FIG. 1, a flow of the heated volume of coolant 208 is pumped from the enclosure 200 via an outlet 214, through a heat exchanger, and back to the nozzle 202. Where the enclosure 200 is part of a system according to the disclosure adapted for start up in cold soak conditions, the flow of coolant delivered to the nozzle 202 will have been heated and the jet 204 will transfer heat to the electronic component 220 to warm it to a safe operating temperature.

While FIG. 2 shows only a single electronic component 220 in the enclosure 200, it will be understood that in other embodiments an enclosure according to the disclosure may include a plurality of electronic components, which may be arranged in an array. Preferably, such an enclosure will also include a corresponding array of submerged nozzles, with each component being impinged by a jet from a nozzle. In other embodiments, some electronic components of the plurality of components are heated or cooled only by the wall jet 206 or the volume of coolant 208.

A cooling system architecture according to the disclosure enables a high power electronics system to start-up at extremely low temperatures in a thermal “soft-start” mode, so that mechanical or structural failures due to thermal shock or a differential thermal expansion rates are minimized or eliminated. It also enables high heat loads to be removed from high heat flux components once a safe operating temperature for the components has been reached. These two advantages work together due to the overall architecture including using submerged jet impingement cooling to remove heat from components, the use of a dielectric coolant with a low pour point, and a cooling loop with a heater.

A cooling loop architecture according to the disclosure includes three significant features. In a first feature, the architecture preferably uses a low pour point, dielectric fluid as the coolant. A preferred coolant is 3M Novec 7500, manufactured by the 3M Company of Maplewood, Minn. Novec 7500 is nonflammable, has a pour point of −100° C., is non-ozone depleting, is a dielectric liquid with a dielectric constant of 5.8, has an environmentally friendly greenhouse warming potential of 100, and has a very low viscosity at cold temperatures. For example, at −50° C. Novec 7500 has a viscosity of 5.5 centistokes (cSt). In comparison, at −50° C. PAO has a viscosity of 568 cSt, or 103 times that of Novec 7500. This means Novec 7500 will be easy to pump at −50° C. and at lower temperatures, allowing for array start-up at −80° C. Also at −80° C. Novec 7500 will not freeze while both a PGW and EGW will be frozen.

In a second feature, the architecture uses jet impingement cooling (JIC) where a jet of coolant impinges directly on a heat producing component. This is possible where the coolant is a dielectric fluid with a low dielectric constant. Novec 7500 is one example of such a fluid. For the purposes of this disclosure a dielectric constant below 10 is considered a low dielectric constant. Mathematical modeling indicates that, using JIC with a low dielectric constant cooling fluid, device temperatures remain acceptably low and accommodate the component's high heat fluxes.

Modeling a jet impingement system according to the disclosure may be performed using any of several mathematical models. One such model is based on submerged jet correlations developed by Womac, Ramadhyani, and Incropera, as reported in Cooling Equations for Impingement Cooling of Small Heat Sources with Single Circular Liquid Jets, ASME Journal of Heat Transfer, Vol. 115, February, 1993, pp. 106-115 (“Womac”). The Womac equation accurately addresses the heat transfer in the impingement zone and in the wall jet zone:

$$\frac{{\overline{Nu}}_{l}}{{Pr}^{0.4}} = 0.785 {Re}_{d}^{0.5} \frac{l}{d} {A}_{r} + 0.0257 {Re}_{L}^{0.8} \frac{l}{L} ( 1 - {A}_{r} )$$

$$where \text{:}$$

$${A}_{r} = \frac{{π ( 1.9 d )}^{2}}{{l}^{2}}$$

$$d = nozzle diameter$$

$$L = \frac{( 0.5 \sqrt{2} - 1.9 d ) + ( 0.5 l - 1.9 d )}{2}$$

$$l = length of the side of the square heat source ( electronic component )$$

$$\overline{Nu} = heater ( electronic component ) average Nusselt number$$

$$Pr = Prandtl number$$

$${Re}_{d} = nozzle Reynolds number$$

$${Re}_{L} = average jet wall length Reynolds number$$

In modeled test systems according to the disclosure, heat transfer coefficients were found to be in the range of 1.07-1.6e04 W/(M²-K) depending on the electronic component's die size using a 0.005 inch diameter jet with 29 psid across the jetting hole. Typical modeled device temperatures are shown in the following table, for a coolant temperature of 50° C. with a flow rate of 0.0026 GPM through a 0.005 inch diameter jet using Novec 7500 as the coolant.

| | | | | JIC Heat | |
|---|---|---|---|---|---|
| | | | | Transfer | Device |
| Example | Die Size | | | Coefficient | Temperature |
| Device | L (mm) | W (mm) | Heat (W) | (Watt/M²-K) | (° C.) |
| #1 | 3.9 | 2.9 | 5 | 1.42E+04 | 80.5 |
| #2 | 3.05 | 5.15 | 3.6 | 1.38E+04 | 66.6 |
| #3 | 2.56 | 2.6 | 2.32 | 1.60E+04 | 72.0 |
| #4 | 21.5 | 21.5 | 31.8 | 1.07E+04 | 70.5 |

In a third feature, the architecture includes a heater in the coolant loop, to provide a thermal “soft start” type of warm-up. In some embodiments, the level of heat is ramped up following a predetermined temperature profile or a “temperature rate of change” profile. When a coolant with a suitably low pour point is used, the coolant will flow in the loop when started up at −80° C., enabling heat produced by the heater to be transported to all loop components to warm them up. Because a heater is used, the array electronics do not have to be powered up in order to produce heat used for warming, thus preventing active devices from being operated at temperatures where they could be unstable or damaged. Furthermore, because electronic devices are not being used to generate heat in such embodiments, transient temperature gradients will be greatly reduced, reducing or eliminating mechanical or structural failures or damage that are induced by differential expansion rates of electronic and/or mechanical components.

Other coolants than 3M Novec 7500 may be used in embodiments of the disclosure having jet impingement cooling and, where necessary, heater-assisted warm up. PAO is a coolant with a suitably low dielectric constant (i.e., less than 10), as are 3M Novec 7600, 3M Fluorinert FC-770, and mineral oil. Some coolants with suitable dielectric constants have pour points that make them suitable only for applications having less stringent start up soak temperature requirements.

Although the present disclosure has been described with an exemplary embodiment, various changes and modifications may be suggested to one skilled in the art. It is intended that the present disclosure encompass such changes and modifications as fall within the scope of the appended claims.

What is claimed is:

1. A temperature regulation system for an electronic component, the system comprising:
a nozzle configured to produce a jet of coolant that impinges on the electronic component, wherein the jet and the electronic component are submerged in a volume of the coolant;
a heat exchanger; and
a pump operable to move a first flow of the coolant from the volume of the coolant, through the heat exchanger, and into the nozzle, thereby forming the jet of coolant.

2. The system of claim 1, wherein the coolant has a dielectric constant less than 10.

3. The system of claim 1, wherein the coolant has a pour point less than −80° C.

4. The system of claim 1, further comprising a heater configured to heat the coolant as it passes from the pump to the nozzle.

5. The system of claim 1, further comprising a bypass valve configured to route the coolant around the heat exchanger.

6. The system of claim 1, further comprising a refrigeration unit coupled to the heat exchanger.

7. The system of claim 1, further comprising a second electronic component mounted to an outer surface of a mounting component, wherein the coolant is conducted through an inner channel of the mounting component, and wherein the pump is further configured to move a second flow of coolant through the inner channel.

8. The system of claim 7, further comprising a flow divider configured to divide the flow of coolant from the heat exchanger into the first flow of coolant to the nozzle and the second flow of coolant to the mounting component.

9. The system of claim 7, further comprising a flow combiner configured to combine the first flow of coolant from the volume of the coolant with the second flow of coolant from the mounting component prior to pumping the flow of coolant through the heat exchanger.

10. The system of claim 1, wherein the nozzle is one of a plurality of nozzles and the electronic component is one of a plurality of electronic components, wherein each nozzle produces a jet that impinges on a corresponding one of the plurality of electronic components, and each jet and each electronic component is submerged in the volume of the coolant.

11. A method of regulating the temperature of an electronic component, the method comprising:
producing a jet of coolant that impinges on the electronic component, wherein the jet and the electronic component are submerged in a volume of the coolant; and
pumping a first flow of coolant from the volume of the coolant, through a heat exchanger, and into the nozzle.

12. The method of claim 11, wherein the coolant has a dielectric constant less than 10.

13. The method of claim 11, wherein the coolant has a pour point less than −80° C.

14. The method of claim 11, further comprising heating the coolant prior to producing the jet of coolant.

15. The method of claim 11, further comprising operating a bypass valve to route the coolant around the heat exchanger.

16. The method of claim 11, further comprising controlling a connection of a refrigeration unit to the heat exchanger.

17. The method of claim 11, further comprising pumping a second flow of coolant through an inner channel of a mounting component having a second electronic component mounted to an outer surface of the mounting component.

18. The method of claim 17, further comprising combining the first flow of coolant from the volume of the coolant with the second flow of coolant from the mounting component prior to pumping the flow of coolant through the heat exchanger.

19. The method of claim 18, further comprising dividing the flow of coolant from the heat exchanger into the first flow to the nozzle producing the jet of coolant and the second flow of coolant to the mounting component.

20. The method of claim 11, wherein producing a jet of coolant that impinges on the electronic component comprises producing a plurality of jets of coolant that impinge on a corresponding plurality of electronic components, and each jet and each electronic component are submerged in the volume of the coolant.
